(19) United States
(12) Patent Application Publication
(10) Pub. No.: US 2018/0026555 A1
(43) Pub. Date: Jan. 25, 2018

(54) Reciprocal Hall Effect Energy Generation Device

(71) Applicant: George Samuel Levy, San Diego, CA (US)

(72) Inventor: George Samuel Levy, San Diego, CA (US)

(21) Appl. No.: 15/623,283

(22) Filed: Jun. 14, 2017

Related U.S. Application Data
(60) Provisional application No. 62/364,077, filed on Jul. 19, 2016.

(51) Int. Cl. H02N 11/00; H01L 43/06; H01L 43/04

(52) U.S. Cl. CPC H02N 11/002; H01L 43/04; H01L 43/06; H01L 37/025

(57) ABSTRACT

When a magnetic field is applied parallel to a layer of thermoelectric material, and an electric field is applied perpendicular to the layer, electrical carriers in the layer follow cyclotron orbits interrupted by one of the layer's surfaces. These interrupted orbits produce a drift current along the layer and perpendicular to both fields. Therefore, the inputs are a magnetic field and an electric field, and the output is a current. The phenomenon differs from the classical Hall Effect in which the inputs are a magnetic field and a current and the output is a voltage. The output current produces electrical energy which can be used immediately, stored for later consumption, converted to another form or transmitted to another location. Layers can be stacked, each layer of the stack mutually reinforcing the electrical field in the adjacent stack layers. Stacked layers can be connected in series or parallel.

This invention claims the benefit of U.S. Provisional Application No. 62/364,077 titled, “Inverse Hall Effect Energy Generation Device” filed on Jul. 19, 2016, and which is hereby incorporated by reference. Applicant claims priority pursuant to 35 U.S.C. Par 119(e)(i).

### FIELD OF THE INVENTION

The present invention relates to thermoelectric devices that exploit an inverse or reciprocal version of the Hall Effect or quantum Hall Effect.

### BACKGROUND

The Hall Effect is a well known phenomenon: a current moving through a conductor perpendicular to a magnetic field generates a voltage perpendicular to both the current and the field. The Hall resistance is defined as the ratio of the generated voltage to the current. The longitudinal resistance is understood to be the resistance along the direction of the current. In other words, if a given voltage difference is produced at the two ends of the conductor, the longitudinal resistance is the ratio of this voltage difference to the current.

The quantum Hall Effect is typically observed at low temperature even though some recent experiments notably in graphene have shown it to be possible near room temperature. When certain materials are subjected to a magnetic field, electrons move in circular orbits in the material and can only acquire discrete energy values. This electronic quantization results in the Hall resistance being a step-wise function of the magnetic field. Corresponding to each step of the Hall resistance, the longitudinal resistance falls to near zero.

### SUMMARY OF THE INVENTION

This invention describes an energy generation device based on a reciprocal version of the Hall Effect. When a magnetic field is applied parallel to a layer of thermoelectric material, and an electric field is applied perpendicular to the layer, electrical carriers in the layer follow cyclotron orbits interrupted by one of the layer's surfaces. These interrupted orbits produce a drift current along the layer and perpendicular to both fields. Therefore, the inputs are a magnetic field and an electric field, and the output is a current. The phenomenon differs from the classical Hall Effect in which the inputs are a magnetic field and a current and the output is a voltage.

This drift current is spontaneous and can only occur near one of the surfaces of the layer where the statistics of the carriers are biased by the combination of magnetic field, electric field and surface.

This reverse Hall Effect can be explained as follows: the magnetic field causes free carriers to follow circular orbits inside the thermoelectric layer. However, near the surface, these orbits are interrupted in an asymmetric manner, giving rise to surface drift currents. In the absence of an electric field, drift currents on opposite sides of the layer have equal amplitudes but opposite directions, and therefore cancel each other out. When an electrical field is applied perpendicular to the layer and perpendicular to the magnetic field, an imbalance is created in the carrier density between the two sides, resulting in one of the surface currents being depleted or pinched off. The surface drift currents on the two sides are not balanced. Therefore, a net current becomes observable and can be exploited for energy production. This energy can be used immediately, stored for later use, converted to another form, or transmitted to a different location.

The effect can be produced by applying a magnetic field perpendicular to a layer or by using materials (such as ferromagnetics) capable of exhibiting the anomalous Hall Effect. The effect can also occur by replacing the thermoelectric material with an oven containing plasma.

Many implementations are envisioned. The first utilizes insulated capacitor plates positioned on the floor and ceiling of a flat-shaped vacuum oven. A magnetic field is applied horizontally, parallel to the plates and an electric field is generated vertically, perpendicularly to the plates by applying a voltage across the plates. The electric field shifts the carriers and associated thermionic activity to one of the plates where, in the presence of the magnetic field, the thermionically emitted carriers follow partial orbits starting and ending at the surface of the plate. The asymmetrical motion of the carriers generates a current that flows along the surface of the plates, and that can be captured by two electrodes located at the edges of the plates.

Implementations can also use the electric field produced in thermoelectric junctions, either N-doped or P-doped. A thin layer of the material is placed between insulated capacitor plates. The layer is thin enough and the doping, moderate enough, to prevent the formation of space charges that would cancel the electric field.

Implementations can also utilize N/intrinsic or P/intrinsic junctions, to produce the electrical field. Implementations can also produce the electric field produced by electrets or ferroelectric materials.

Layers can be stacked together in a manner that the electric fields in the layers mutually reinforce each other and such that the currents produced by the layers add up (parallel connection) or such that the voltages add up (series connection).

Applications of this technology include heating, cooling, electrical energy production and lighting. Power supplies and coolers can be fabricated as integral subcomponents of semiconductor chips or modules.

This invention is therefore, an energy generator which comprises a layer of semiconductor material. The semiconductor material can be thermoelectric material with a preferably large ZT factor, for example greater than 0.5, greater than 1.0, greater than 1.5 or greater than 2. The ZT factor is a figure of merit for thermoelectric defined as ZT=σS²T/K, where σ is the electrical conductivity, S is the Seebeck coefficient, T is the temperature, and κ is the thermal conductivity.

The thermoelectric material can comprise Bismuth chalcogenides such as Bismuth Telluride or Bismuth Selenide. The thermoelectric material can also comprise Lead Telluride or Lead Selenide or Tin Telluride or Tin Selenide. The thermoelectric layer can also comprise inorganic clathrate, magnesium with group IV compounds such as Silicon, Germanium or Tin). The thermoelectric material can also include Skutterudite. The thermoelectric material can also include half Heusler alloys. The thermoelectric material can also include graphene. The readier is referred to the vast literature on thermoelectric materials.

The layer holds electrical carriers which can be electrons or holes. A magnetic field is applied parallel to the layer, the magnetic field can be produced by a permanent magnet or an electro-magnet. An electric field is applied perpendicular to the layer. This field can be produced by insulated capacitor plates, a semiconductor junction, electrets or ferroelectric material.

In accordance with this invention, a voltage is generated between two opposite ends of the layer, along an axis in the plane of the layer and perpendicular to the magnetic field and to the electric field. Electrodes connected to the two ends of the layer capture this voltage, allowing a current to flow. The voltage and current represent useful electrical energy that can be used immediately, stored for later use, converted to a different form or transmitted to be used at a different location.

### BRIEF DESCRIPTION OF THE DRAWINGS

FIG. 1 illustrates the motion of an electrical carrier near a surface, when subjected to a magnetic field.

FIG. 1A shows that the Hall Effect generates surface drift currents on opposite surfaces of a layer. These currents have equal amplitudes but opposite directions.

FIG. 1B shows that an electric field can pinch off one of the surface currents on either side of a layer, resulting in a net current along the layer.

FIG. 2 shows the movement of carriers near the surface of a layer, in the quantum Hall Effect.

FIG. 2A shows the conventional interpretation of the quantum Hall Effect as a step function in the Hall resistance and a near zero (or zero) resistance in the longitudinal resistance.

FIG. 3 illustrates the basic idea in this invention. The Hall Effect generates two antiparallel Hall currents on opposite sides of a layer. These two Hall currents cancel each other out exactly. Pinching off one of the Hall currents by means of an electric field results in a net current out of the layer.

FIG. 3A illustrates the basic idea of the invention when the magnetic field is replaced by magnetization of the material.

FIG. 4 shows an implementation of this invention using electrons or ions between insulated capacitor plates in a vacuum chamber.

FIG. 5 shows an implementation of this invention using a thermoelectric material in a sandwich between insulated capacitor plates.

FIG. 6 shows an implementation of this invention using a thermoelectric material forming a junction between an N-doped and an intrinsic material.

FIG. 7 shows an implementation of this invention using a thermoelectric material forming a junction between a P-doped and an intrinsic material.

FIG. 8 shows how the output of the device can be increased by stacking individual devices.

FIG. 9 shows a stack of N material in a sandwich between capacitor plates and connected in series.

FIG. 10 provides an orthogonal view of FIG. 9, also showing a stack of N material in a sandwich between capacitor plates and connected in series.

FIG. 11 shows a stack of N/intrinsic junctions connected in series.

FIG. 12 shows a stack or N/intrinsic and P/intrinsic junctions connected in parallel.

### DETAILED DESCRIPTION

The description of this invention includes a first section covering the theory and a second section covering physical implementations.

### Theory

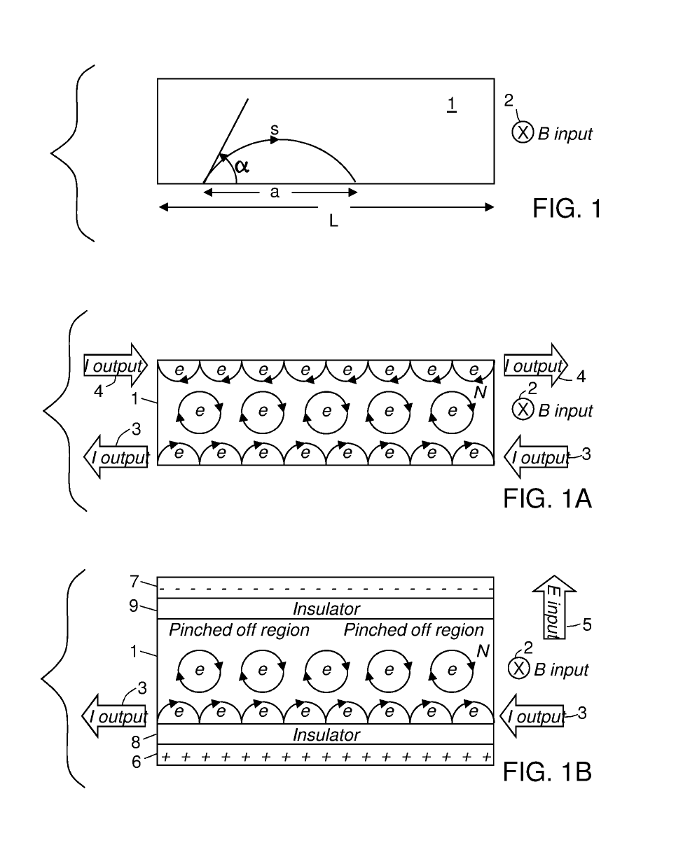

A theory is presented herewith for a better understanding of the invention, but it is understood that the invention is not tied to the theory. A semi-classical method shall be used to calculate the drift current produced as shown in FIG. 1 on the surface of a thermoelectric layer 1.

Thermoelectrics are remarkable semiconductor materials because of the relatively low coupling between the electrical carriers—electrons or holes—and the supporting crystal lattice. These materials owe their properties to a high conductivity σ of the electrical carriers and low thermal conductivity κ of the heat phonons. Their thermoelectric efficiency is described by the figure of merit Z=S² σT/κ where S is the Seebeck coefficient. Remarkably, electrical carriers in these materials can be considered to be in a gas phase. Both heat phonons in the crystal lattice and electrical carriers transport heat but because of their mutual low coupling these two sets of heat carriers may have different temperatures. In other words, electrical carriers can have a temperature different from the lattice.

The thermoelectric material 1 is assumed to be highly conductive, that is mostly transparent to electrical carriers but operating in depletion mode that is mostly devoid of electrical carriers. Let the thermoelectric material be N-doped. Consider an electron with charge q, mass m and subjected to a magnetic field B 2 parallel to the surface of the layer 1. The question being asked is how much current is produced along the length L of the layer by this carrier as it bounces near the surface.

Let the carrier colliding against the insulator surface be thermalized and re-emitted. At first let us assume that the re-emitted carrier only travels as shown in FIG. 1, in a vertical plane perpendicular to the field B 2, with velocity v along a circular s arc that begins and ends at the surface of the thermoelectric layer 1. If the charge is negative and the magnetic field points into the plane of the drawing, the carrier always travels clockwise. On the bottom surface, the endpoint is always to the right of the starting point generating a surface drift current to the left and vice versa, on the top surface the endpoint is always to the left of the starting point and the surface drift current is to the right.

The clockwise movement of the carrier along arc s produces a current along the chord a on the surface of the layer. Let the carrier leave the surface at a tangential angle α. The length of the arc is then s=2αr where α can range from 0 for a zero-length arc to π for a full orbit. The travel time from the starting point to the ending point along the arc is

$$t = \frac{2 α r}{v}$$

which is also the travel time of the charge along the chord a. The surface drift current along a is

$${I}_{a} = \frac{q}{t} .$$

The current I(α) over the entire length L of the layer needs to be scaled accordingly by a/L:

$$I ( α ) = \frac{a}{L} \frac{q}{t} = \frac{a}{L} \frac{qv}{2 α r} . \qquad ( 1 )$$

Since a=2r sin(α):

$$I ( α ) = \frac{qv}{L} \frac{sin ( α )}{α} . \qquad ( 2 )$$

Now assuming a carrier density n at the surface, the current becomes

$$I ( α ) = \frac{nq}{2 L} \frac{sin ( α )}{α} v . \qquad ( 3 )$$

As mentioned above, this current represents only the contribution of carriers moving in a plane perpendicular to the field. To get the total surface drift current, we integrate equation (3) using a half Maxwell-Boltzmann distribution expressed in polar coordinate form:

I=∫_{-π/2}^{π/2}∫₀^{π/2}∫₀^{∞}I(a)f(θ,φ,v)dvdθdφ. (4)

However, v is constant over the domain of integration i.e., f(θ,φ,v)=f(v). Hence, we can treat each integral in equation (4) separately. Substituting equation (3) into equation (4) yields:

$$I = {\int }_{- π / 2}^{π / 2} {\int }_{0}^{π / 2} {\int }_{0}^{∞} \frac{nq}{2 L} \frac{sin ( α )}{α} vf ( θ , ϕ , v ) dv d θ d ϕ . \qquad ( 5 )$$

Since

$$θ = \frac{π}{2} - α ,$$

we can express

$${\int }_{- π / 2}^{π / 2} \frac{sin ( α )}{α} d θ as - {\int }_{0}^{π} \frac{sin ( α )}{α} d α$$

### Hence

$$I = - \frac{nq}{2 L} {\int }_{0}^{π} \frac{sin ( α )}{α} d θ {\int }_{0}^{π / 2} d ϕ {\int }_{0}^{∞} vf ( v ) dv . \qquad ( 6 )$$

from equation 21 in [1]:

$$\overline{v} = {\int }_{0}^{∞} vf ( v ) dv = {\int }_{0}^{∞} {( \frac{m}{2 π {k}_{B} T} )}^{3 / 2} exp ( \frac{- {mv}^{2}}{2 {k}_{B} T} ) 4 π {v}^{3} dv . \qquad ( 7 )$$

and using ∫₀^{∞} x exp(−x)dx=Γ(2)=1 we can solve the integral in equation (7)

$$\overline{v} = {\int }_{0}^{∞} vf ( v ) dv = {( \frac{8}{π} )}^{1 / 2} {( \frac{{k}_{B} T}{m} )}^{1 / 2} . \qquad ( 8 )$$

The other two integrals in equation (6) are easy to solve, i.e.,

$${\int }_{0}^{π} \frac{sin ( α )}{α} d α = Si ( π ) = 1.85 and {\int }_{0}^{π / 2} d ϕ = \frac{π}{2} .$$

### Therefore:

$$I = - 1.85 \frac{nq}{2 L} \frac{π}{2} {( \frac{8}{π} )}^{1 / 2} {( \frac{{k}_{B} T}{m} )}^{1 / 2} = - 1.85 {( \frac{π}{2} )}^{1 / 2} \frac{nq}{L} {( \frac{{k}_{B} T}{m} )}^{1 / 2} . \qquad ( 9 )$$

As shown in FIG. 1A, the current 3 flowing on the bottom surface is moving left, and the one 4 on the top surface is moving right. The currents have equal magnitudes but opposite directions resulting in a zero net observable current.

Let us now apply an electric field E 5 produced by applying a voltage V across the capacitor plates 5 and 6 insulated from the thermoelectric layer by insulators 8 and 9 as shown in FIG. 1B. If the magnetic force is significantly larger than the electric force (qvB>>qE) we can assume that the carriers still follow mostly circular orbits and that the calculations above are correct except that the electric field shift modifies the concentration of carriers by shifting them from one side of the layer 1 to the other. It shall be assumed that the doping is low to moderate and that the layer is thin enough that the number of carriers shifted by the electric field is insufficient to significantly alter the electric field across the thermoelectric material. In other words, the layer is operated in the depletion zone and the electric field E is not canceled by the shift in the carriers. In Filed Effect Transistor terminology, the electric field “pinches off” the carries on one side of the layer and enriches them on the other side.

The shift in carriers results in a difference Δn in carrier concentration between the two sides of the layer. Let the thermal interaction between the carriers and the insulator surface define the carriers' statistics as maxwellian. The change in carrier concentration between the top and bottom of the layer can be written as

$${n}_{top} = {n}_{bottom} exp ( \frac{- q {V}_{z}}{{k}_{B} T} ) . \qquad ( 10 )$$

The difference Δn is then

$$Δ n = {n}_{bottom} ( 1 - exp ( \frac{- q {V}_{z}}{{k}_{B} T} ) ) . \qquad ( 11 )$$

The net current for the top and bottom surfaces of the layer is obtained by combining equations (9) and (11), yielding

$$Δ I = - 1.85 {( \frac{π}{2} )}^{1 / 2} \frac{nq}{L} {( \frac{{k}_{B} T}{m} )}^{1 / 2} exp ( \frac{qV}{{k}_{B} T} ) . \qquad ( 12 )$$

which is a measurable current.

Remarkably the only contribution of the magnetic field to equation (12) is the sign indicating that the current at the bottom of the layer flows to the left, and the one at the top of the layer, flows to the right. One must recognize that the equation represents a simplified model of the overall process and that the size of the magnetic field is actually important. In a weak field, the current at the top of the layer and the one at the bottom move away from their respective surfaces and into the bulk, and cancel each other. It is therefore important for the field to be strong enough that the orbits of the carriers have a radius significantly smaller than the thickness of the layer. The radius can be obtained by equating the Lorentz force to the centrifugal force.

$$F = q vB = \frac{{mv}^{2}}{r} . \qquad ( 13 )$$

and solving r yields:

$$r = \frac{mv}{qB} . \qquad ( 14 )$$

Hence

$$\frac{mv}{qB} << Thickness. \qquad ( 15 )$$

Using the average value for v obtained from equation (8) we get

$${( \frac{8}{π} )}^{1 / 2} \frac{1}{qB} {( {mk}_{B} T )}^{1 / 2} << Thickness. \qquad ( 16 )$$

Equation (12) indicates that a current can be spontaneously generated. How much voltage can be produced? If the current path is open circuit, electrical charges are shifted in the plane of the layer and accumulate, giving rise to a counter voltage that eventually equals V stopping any more charge displacement.

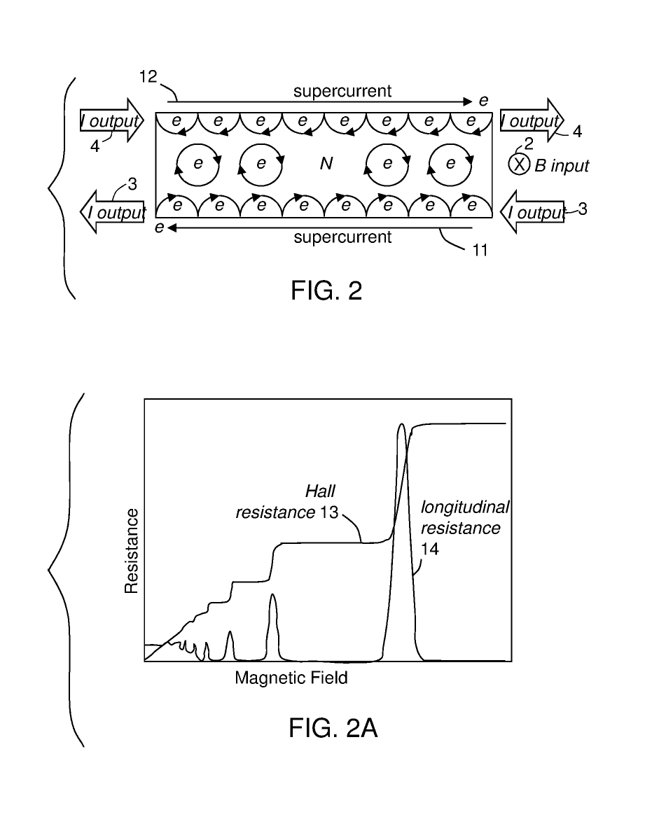

The well know quantum Hall Effect illustrated in FIGS. 2-2A can also operate in inverse or reciprocal mode. The quantum Hall Effect relies on surface carriers as already explained in FIG. 1-1B. For certain values of the magnetic field, Hall resonance states become observable and correspond to the quantization of the electronic energies as shown in FIG. 2A. The Hall resistance becomes a step-wise function of the magnetic field. In addition, when an electron flowing along the surface encounters an obstacle in its path, the reflected wave destructively interferes with itself because of the ½ spin and the wave nature of the electrons. No reflection occurs and the electron goes through or around the obstacle unimpeded, resulting in zero resistance. The surface drift currents 3 and 4 become supercurrents 11 and 12, manifesting themselves as a drastic lowering of the longitudinal resistance.

As the magnetic field is varied, each resulting quantum energy state of the electrons corresponds to a step in the Hall conductivity and a dip in the longitudinal resistance of the layer. A drift supercurrent 12 is carried by the top surface in one direction, and another drift supercurrent 11 is carried by the bottom surface in the opposite direction, the current sum being zero. Conventionally, the quantum Hall properties are not expressed in terms of currents which are not readily measurable, but of Hall resistance 13 and longitudinal resistance 14. The Hall resistance is the ratio of Hall voltage to current and is a step function because of quantization effects. The longitudinal resistance is the ratio of longitudinal voltage to current and drops to nearly zero or to zero for each step of the Hall resistance function. In analogy to the reciprocal Hall Effect described above in this invention, the reciprocal quantum Hall Effect produces spontaneous supercurrents on each side of a layer supporting a quantum Hall Effect. When an electric field is applied perpendicularly to the layer, one of the supercurrents 11 and 12 currents is pinched off and the other current becomes observable.

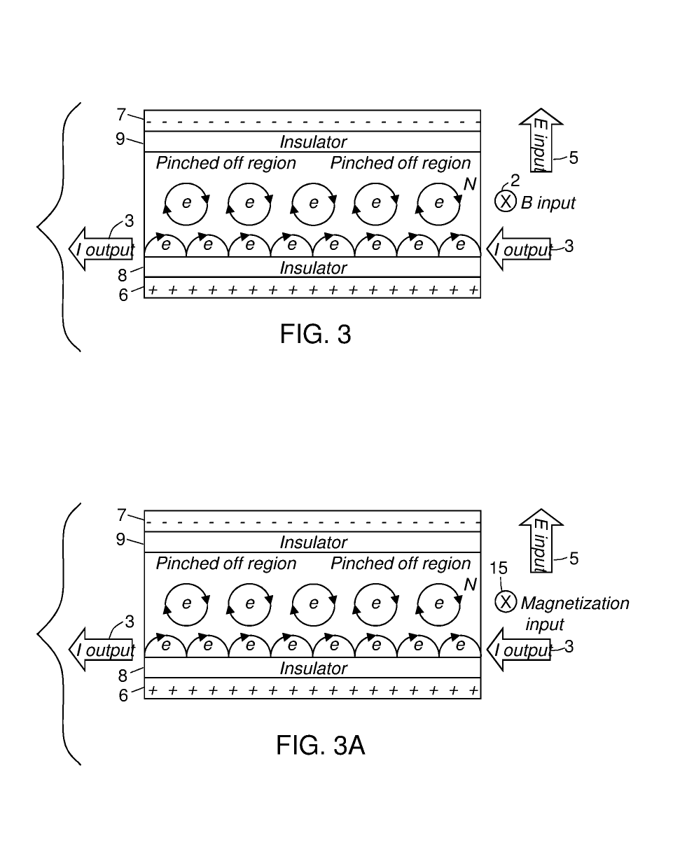

FIG. 3 illustrates the basic idea of this invention. If an electrical field 5 is applied perpendicularly to the top and bottom surfaces of the layer 1 and to the magnetic field 2, then the electrical carriers, (e.g., electrons) are pushed to one side of the layer, leaving the other side depleted of carriers. In Field Effect Transistors technology, this phenomenon is called pinching off. The net imbalance of carriers between the two surfaces results in a net output current 3. The electric field 5 can be produced in several ways, for example by insulated capacitor plates 6 and 7 as shown in the drawing, or by electrets or junctions as shall be explained further below.

As can be appreciated, this effect can be produced by the Hall Effect or the quantum Hall Effect, but, for this effect to be observable, the number of carriers needs to be limited. If the number of carriers is too large, the shift in carriers produced by the electric field generates space charges that cancel the electric field in the bulk of the material. In other words, the layer needs to operate in depletion mode. In conventional Hall Effect experiments the effect is not observed because the material usually has a high conductivity.

The preceding discussion describes the reciprocal Hall Effect produced by charged carriers behaving in a gas phase in a thermoelectric material. The same effect can also be generated by a plasma enclosed in an oven and having thermionic interaction with the walls of the oven. The same effect can also be produced by a topological insulator in which carriers are free to move on the surface.

In FIG. 3A, the magnetic field is replaced by magnetization 15 of the material, relying on the anomalous Hall Effect, thereby allowing a reduced magnetic field or the elimination of the field altogether.

Another interesting and useful phenomenon produced by the reciprocal Hall Effect is the temperature gradient along a layer capable of carrying a reciprocal Hall current. This temperature gradient occurs as an Onsager reciprocal of the current.

### Implementation

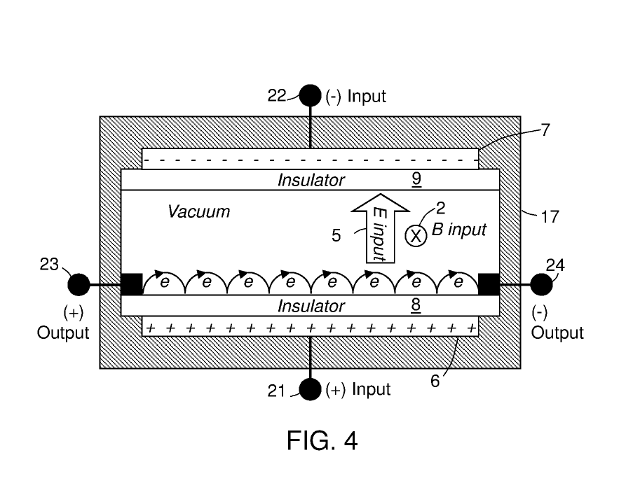

This effect can be produced in many different ways as shown in FIGS. 4 to 12.

FIG. 4 shows this effect operating at high temperature. Insulated capacitor plates 6 and 7 are positioned on opposite walls of a flat oven 17. The plates 6 and 7 are conductive and covered by insulators 8 and 9. A magnetic field 2 is applied parallel to the plates 6 and 7 and produced either by an electromagnet or by a permanent magnet. An electric field 5 is produced perpendicularly to the plates 6 and 7 by applying a voltage across the plates by means of electrodes 21 and 22. The temperature is high enough to enable thermionic (either electrons or ions, but preferably electrons) emission. The ionic density or electronic density should be low enough as not to cause a significant charge displacement between the opposite walls of the oven 17, which would cancel the electric field produced by the capacitor plates 6 and 7. Electrical carriers bouncing off the floor and ceiling of the oven 17 produce a flow along the surface of the insulator and a current can be generated between two electrodes 23 and 24 located at the edges of the insulator. Thermionic emission can be facilitated by fabricating a sprinkling of quantum dots in the insulator 8.

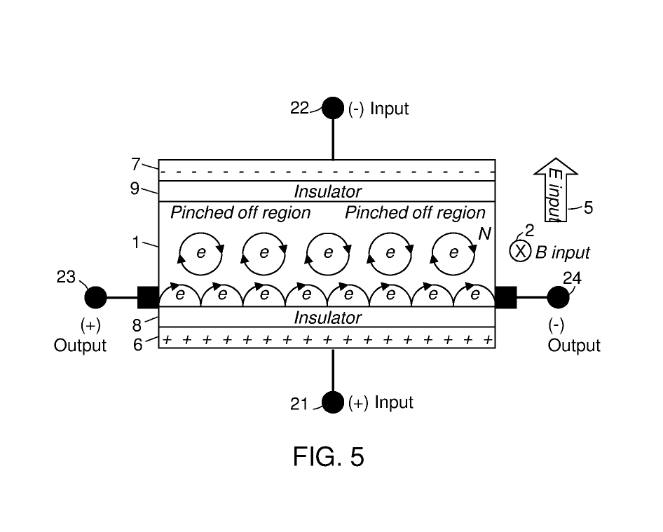

FIG. 5 shows a low temperature or room temperature implementation using a structure very like the one already discussed above except that it utilizes a thermoelectric layer 1 (for example N-doped) in a sandwich between two insulated capacitor plates 6 and 7 connected to electrodes 21 and 22 respectively. The current is captured by electrodes 23 and 24. The material in FIG. 5 is N doped and the carriers are electrons but the same applies to P doped material carrying holes, with the polarity of the magnetic and electric field appropriately reversed. The layer 1 should be thin enough and its doping, moderate enough for the layer to operate in the depletion zone. In other words, the carrier density should be low enough that no significant space charge accumulates on either side of the layer, which would cancel the electrical field 5 across the layer 1.

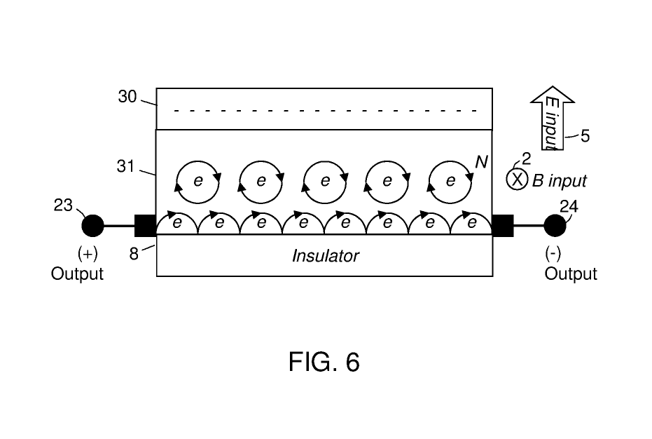

FIG. 6 is a thermoelectric implementation in which the electric field 5 is produced by a semiconductor junction between N doped material 30 and intrinsic material 31. The electrons are pulled toward the insulator 8 by the field 5 across the junction.

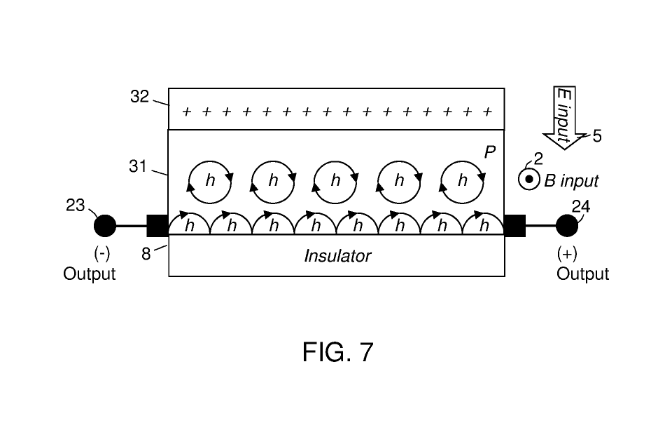

FIG. 7 shows an implementation identical to the one shown in FIG. 6 except that the N material is replaced by P material 32 and the carriers are holes. The electric field 5, the magnetic field 2 and the polarity of the electrodes 23 and 24 are reversed.

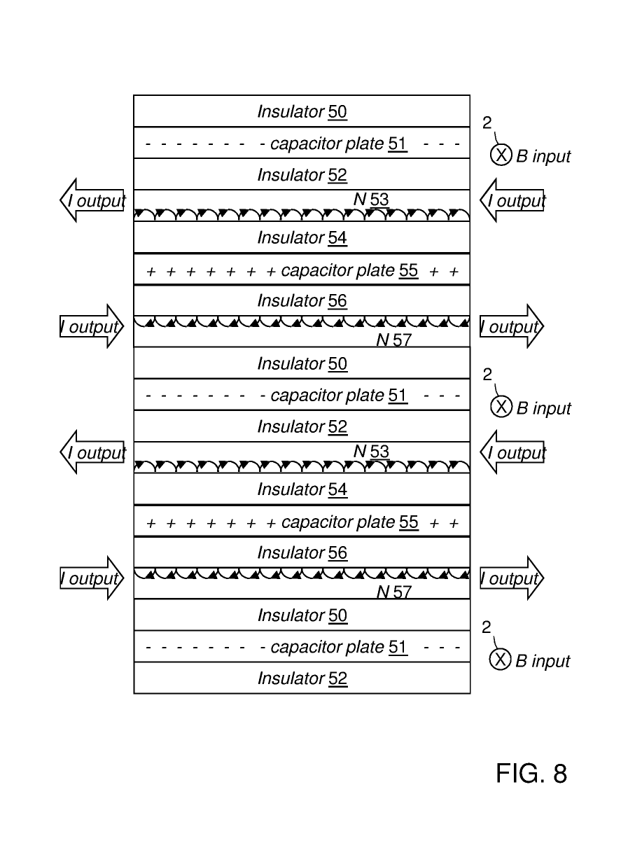

It is possible to stack the devices of FIGS. 3 to 7. The example in FIG. 8 shows interleaved layers including insulator 50, negative capacitor plate 51, insulator 52, N material 53, insulator 54, positive capacitor plate 55, insulator 56, N material 57, these layers repeating an arbitrary number of times. Clearly, stacks of devices shown in FIGS. 3-7 can also be built made of either N material or P material.

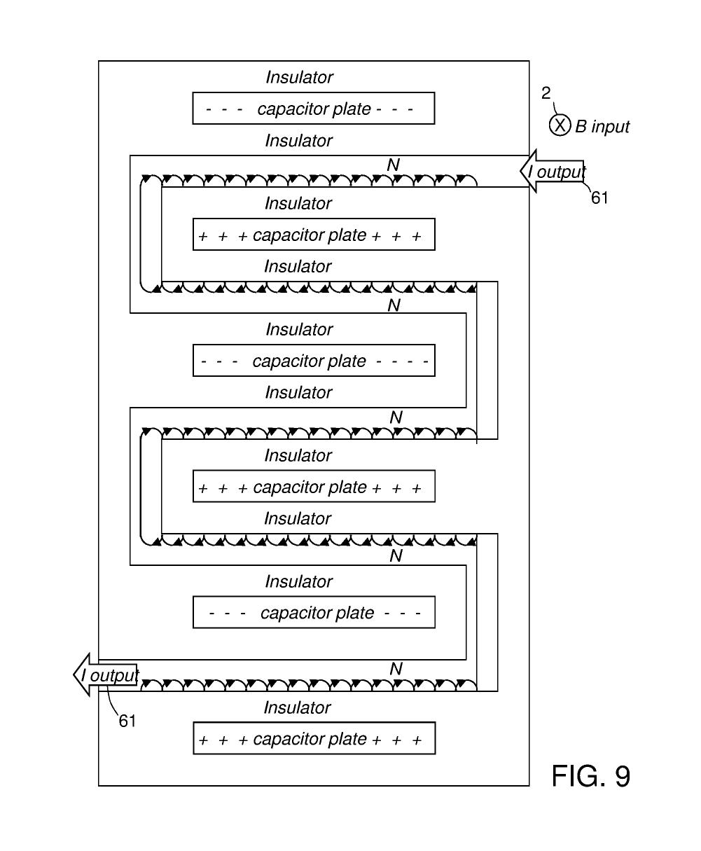

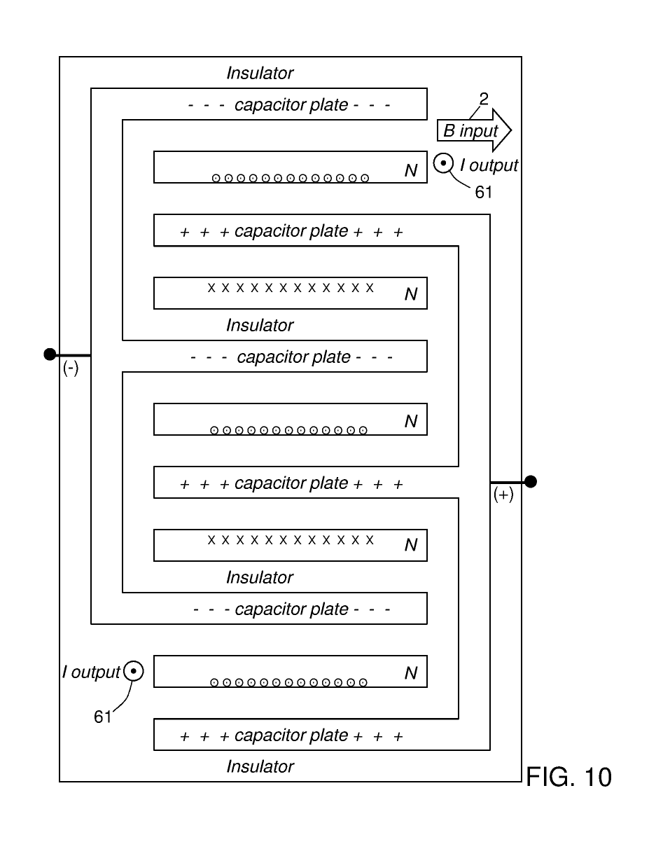

FIGS. 9 and 10 show how multiple layers can be connected together. These two figures are perpendicular cross-section views of the layers. In FIG. 9 the magnetic field 2 is perpendicular to the plane of the drawing, and in FIG. 10 the magnetic field 2 is parallel to the plane of the drawing. In FIG. 9 the electric current 61 is parallel to the plane of the drawing and in FIG. 10 the current 61 is perpendicular to the plane of the drawing.

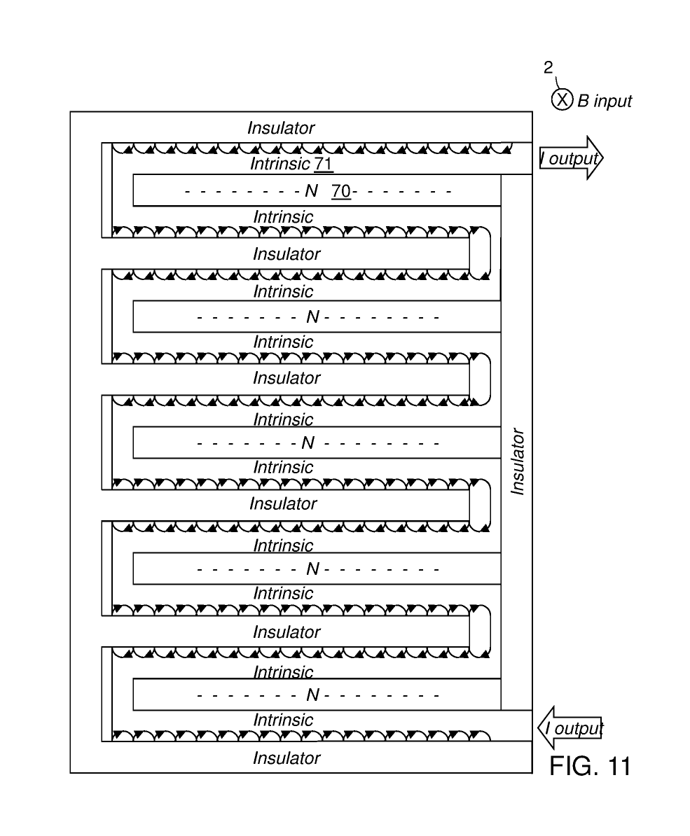

FIG. 11 shows how layers formed of N material 70 and intrinsic material 71 can be stacked and electrically connected in series. Clearly the same can be done with P material.

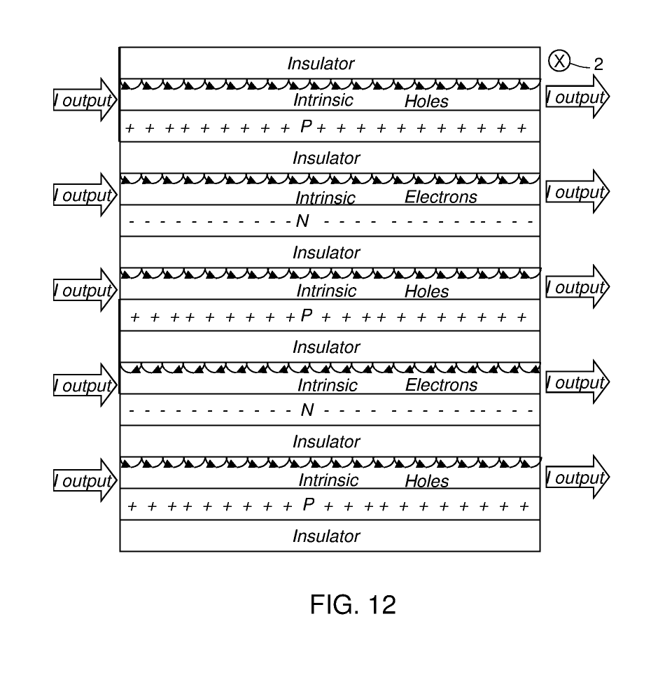

FIG. 12 illustrates how N/intrinsic and P/intrinsic junctions can be stacked together. The outputs can be connected either in parallel or in series. Junctions can also be formed by joining N+ and N material and by joining P+ and P material.

In addition, material (such as ferromagnetics) capable of anomalous Hall Effect or anomalous quantum Hall Effect can also be used. These materials have the special property of enabling the Hall Effect in the presence of a weak magnetic field or even in the absence of a magnetic field altogether. The devices described in FIGS. 3-12 could utilize such materials.

Furthermore, the electric field can be produced by ferroelectric or by electrets.

### Materials

Materials suitable for this application include those with good thermoelectric properties, those with strong Hall Effect, anomalous Hall Effect, quantum hall Effect, anomalous quantum Hall Effect, and those recognized as topological insulators. There is a long list of such materials mentioned in the technical literature.

While the above description contains many specificities, the reader should not construe these as limitations on the scope of the invention, but merely as exemplifications of preferred embodiments thereof. Those skilled in the art will envision many other possible variations within its scope. Accordingly, the reader is requested to determine the scope of the invention by the appended claims and their legal equivalents, and not by the examples which have been given.

### REFERENCES

1. G. Levy, Quantum Game Beats Classical Odds—Thermodynamics Implications, Entropy 2015, 17, 7645-7657; doi:10.3390/e17117645.
2. Levy, G. S., The Reciprocal Hall Effect, CPT symmetry and the Second Law. The Open Science Journal of Modern Physics, 2017 (in press).
3. Levy, G. S., The Faraday Isolator, Detailed Balance and the Second Law. Journal of Applied Mathematics and Physics, 5, 889-899. (2017) doi: 10.4236/jamp.2017.54078.
4. Levy, G. S., Playing Rock, Paper, Scissors in Non-Transitive Statistical Thermodynamics. Journal of Applied Mathematics and Physics, 5, [TBD]

I claim:

1. An energy generator comprising:
a) a layer composed of semiconductor material, said layer holding electrical carriers;
b) a means for producing a magnetic field parallel to said layer;
c) a means for producing an electric field perpendicular to said layer, said means for producing an electric field being electrically insulated from said layer;
d) said layer having two ends located along an axis in a plane of said layer and perpendicular to both said magnetic field and said electric field;
e) electrodes in contact at each of said ends of said layer
a voltage being produced between said ends of said layer, said electrodes capturing an electrical current, said voltage and said current representing useful electrical energy to be used, stored, converted or transmitted.

2. The energy generator of claim 2 wherein said semiconductor material is a thermoelectric material.

3. The energy generator of claim 2 wherein said thermoelectric material as a ZT factor greater than 0.5.

4. The energy generator of claim 2 wherein said thermoelectric material as a ZT factor greater than 1.

5. The energy generator of claim 2 wherein said thermoelectric material as a ZT factor greater than 1.5.

6. The energy generator of claim 2 wherein said thermoelectric material comprises Bismuth chalcogenides.

7. The energy generator of claim 6 wherein said thermoelectric material comprises Bismuth Telluride or Bismuth Selenide.

8. The energy generator of claim 2 wherein said thermoelectric material comprises Lead Telluride.

9. The energy generator of claim 2 wherein said thermoelectric material comprises Lead Selenide.

10. The energy generator of claim 2 wherein said thermoelectric material also comprises Tin Telluride.

11. The energy generator of claim 2 wherein said thermoelectric material also comprises Tin Selenide.

12. The energy generator of claim 2 wherein said thermoelectric material also comprises Graphene.

13. The energy generator of claim 1 wherein said means for producing a magnetic field is a permanent magnet or an electromagnet.

14. The energy generator of claim 2 wherein said means for producing an electric field comprises capacitor plates, said capacitor plates being insulated from said layer.

15. The energy generator of claim 2 wherein said means for producing an electric field comprises a semiconductor junction.

16. The energy generator of claim 2 wherein said means for producing an electric field comprises electrets or ferroelectric materials.
